(19) United States
(12) Patent Application Publication
(10) Pub. No.: US 2013/0009241 A1
(43) Pub. Date: Jan. 10, 2013

(54) SEMICONDUCTOR DEVICE AND METHOD FOR MANUFACTURING SAME

(75) Inventor: Tetsuo MATSUDA, Ishikawa-ken (JP)

(73) Assignee: Kabushiki Kaisha Toshiba, Tokyo (JP)

(21) Appl. No.: 13/423,138

(22) Filed: Mar. 16, 2012

(30) Foreign Application Priority Data
Jul. 5, 2011 (JP) 2011-149469

(51) Int. Cl. H01L 29/78; H01L 21/336

(52) U.S. Cl. 257/331; 257/329; 438/268; 438/270; 257/E29.262; 257/E21.41

(57) ABSTRACT

According to one embodiment, a semiconductor device includes a drain layer, a drift, a base, a source region, a plurality of gates provided on the drift region, the base, and the source region, and arranged in a manner spaced apart from each other, a first interlayer insulating film arranged between the plurality of gates on the source region, a gate interconnection film provided on the first interlayer insulating film and the gate, a second interlayer insulating film provided on the gate interconnection film, an inetconnection film provided on the second interlayer insulating film and connected in common to the source region, the interconnection film filling the contact hole provided between each of the gates in the second interlayer insulating film, the gate interconnection film and the first interlayer insulating film and an insulating film arranged between the gate interconnection film and the interconnection film in the contact hole.

### CROSS-REFERENCE TO RELATED APPLICATIONS

This application is based upon and claims the benefit of priority from the prior Japanese Patent Application No. 2011-149469, filed on Jul. 5, 2011; the entire contents of which are incorporated herein by reference.

### FIELD

Embodiments described herein relate generally to a semiconductor device and a method for manufacturing the same.

### BACKGROUND

A power MOS transistor (Power Metal-Oxide-Semiconductor Field-Effect Transistor) refers to a field effect transistor designed so as to handle a large amount of electric power. As a power MOS transistor, there are a high withstand voltage MOS transistor having a source-drain voltage tolerance not less than 200 V, and a low withstand voltage MOS transistor having a source-drain voltage tolerance not more than 200 V.

In a low withstand voltage MOS transistor, the reduction of the ON-resistance contributes to power saving, cost reduction, and improvement of performance.

The ON-resistance generally refers to the resistance between the source and drain when the transistor is in an on-state. When the ON-resistance is expressed by RonA [Ωmm²], it is a product of the resistance of the entire transistor and the area of the transistor part. When the area occupied by the part where electric current is flowing doubles in a transistor region having the same area, RonA is reduced to half.

Therefore, in order to reduce RonA, two measures are effective, namely, a measure to reduce the resistance value of the current pathway, and a measure to increase the occupation area rate of the current pathway.

A low withstand voltage MOS transistor is an individual semiconductor in which a single chip has only one function. A single gate signal controls the electric current between the source and drain of the entire chip. Accordingly, in the arrangement of gate electrode, either a stripe structure for ease of bundling gate signals, or a mesh structure having a gate electrode also in the direction perpendicular to the stripe has been adopted.

### BRIEF DESCRIPTION OF THE DRAWINGS

FIG. 1 is a schematic perspective view illustrating a semiconductor device according to a first embodiment;

FIG. 2 is a schematic cross-sectional view taken along the A-A′ plane shown in FIG. 1, illustrating the semiconductor device according to the first embodiment;

FIG. 3 is a schematic cross-sectional view taken along the B-B′ plane shown in FIG. 1, illustrating the semiconductor device according to the first embodiment;

FIG. 4A is a schematic perspective view illustrating a method for manufacturing the semiconductor device according to the first embodiment;

FIG. 4B is a schematic perspective view taken along the A-A′ plane shown in FIG. 4A, illustrating the method for manufacturing the semiconductor device according to the first embodiment;

FIG. 5A is a schematic perspective view illustrating the method for manufacturing the semiconductor device according to the first embodiment;

FIG. 5B is a schematic perspective view taken along the A-A′ plane shown in FIG. 5A, illustrating the method for manufacturing the semiconductor device according to the first embodiment;

FIG. 6A is a schematic perspective view illustrating the method for manufacturing the semiconductor device according to the first embodiment;

FIG. 6B is a schematic perspective view taken along the A-A′ plane shown in FIG. 6A, illustrating the method for manufacturing the semiconductor device according to the first embodiment;

FIG. 7A is a schematic perspective view illustrating the method for manufacturing the semiconductor device according to the first embodiment;

FIG. 7B is a schematic perspective view taken along the A-A′ plane shown in FIG. 7A, illustrating the method for manufacturing the semiconductor device according to the first embodiment;

FIG. 8A is a schematic perspective view illustrating the method for manufacturing the semiconductor device according to the first embodiment;

FIG. 8B is a schematic perspective view taken along the A-A′ plane shown in FIG. 8A, illustrating the method for manufacturing the semiconductor device according to the first embodiment;

FIG. 9A is a schematic perspective view illustrating the method for manufacturing the semiconductor device according to the first embodiment;

FIG. 9B is a schematic perspective view taken along the A-A′ plane shown in FIG. 9A, illustrating the method for manufacturing the semiconductor device according to the first embodiment;

FIG. 10 is a schematic cross-sectional view illustrating a semiconductor device according to a second embodiment;

FIG. 11A is a schematic perspective view illustrating the method for manufacturing the semiconductor device according to the second embodiment;

FIG. 11B is a schematic process cross-sectional view taken along the A-A′ plane shown in FIG. 11A, illustrating the method for manufacturing the semiconductor device according to the second embodiment;

FIG. 12A is a schematic planar view illustrating a semiconductor device according to a comparative example 1;

FIG. 12B is a schematic cross-sectional view taken along the A-A′ plane shown in FIG. 12A, illustrating the semiconductor device according to the comparative example 1;

FIG. 13A is a schematic cross-sectional view illustrating a semiconductor device according to a comparative example 2;

FIG. 13B is a schematic cross-sectional view taken along the A-A′ plane shown in FIG. 13A, illustrating the semiconductor device according to the comparative example 2;

FIG. 14 is a schematic cross-sectional view illustrating a semiconductor device according to a third embodiment;

FIG. 15 is a schematic cross-sectional view illustrating a semiconductor device according to a fourth embodiment; and

FIG. 16 is a schematic cross-sectional view illustrating a semiconductor device according to a fifth embodiment.

### DETAILED DESCRIPTION

In general, according to one embodiment, a semiconductor device includes a drain layer of a first conductivity type, a drift region of the first conductivity type provided on the drain layer and having an effective impurity concentration lower than the effective impurity concentration of the drain layer, a base of a second conductivity type provided on the drift region, a source region of the first conductivity type provided on the base, a plurality of gates provided on the drift region, the base, and the source region, and arranged in a manner spaced apart from each other, a first interlayer insulating film arranged between the plurality of gates on the source region, a gate interconnection film provided on the first interlayer insulating film and the gate, a second interlayer insulating film provided on the gate interconnection film, an interconnection film provided on the second interlayer insulating film and connected in common to the source region, the interconnection film filling the contact hole formed between each of the gates in the second interlayer insulating film, the gate interconnection film and the first interlayer insulating film and an insulating film arranged between the gate interconnection film and the interconnection film in the contact hole. The gate has a gate electrode and a gate insulating film arranged between the gate electrode, and the drift region, the base and the source region. The gate interconnection film is electrically connected in common to the gate electrode of the plurality of gates. The gate electrode and the gate interconnection film are insulated from the interconnection film inside the contact hole by the first interlayer insulating film and the insulating film.

According to another embodiment, a method for manufacturing semiconductor device includes processes of forming an insulating film on a semiconductor substrate having formed, on a drain layer of a first conductivity type, a drift region of the first conductivity type having an effective impurity concentration lower than the effective impurity concentration of the drain layer, forming a conductive film on the insulating film, etching the conductive film and the insulating film to form, on the semiconductor substrate, a plurality of gates including a gate electrode made of the conductive film and a gate insulating film made of the insulating film, introducing impurities into an upper layer part of the semiconductor substrate using the plurality of gates as a mask to form a base of the second conductivity type, forming a side wall insulating film all over the side face of each the gates, introducing impurities into an upper layer part of the base using the plurality of gates and the side wall insulating film as a mask to form a source region of the first conductivity type, forming a first interlayer insulating film on the semiconductor substrate to fill the space between the plurality of gates, forming, on the plurality of gates, the side wall insulating film, and the first interlayer insulating film, a gate interconnection film electrically connected to the gate electrode exposed on the upper faces of the plurality of gates, forming a second interlayer insulating film on the gate interconnection film, forming a contact hole reaching the source region on the second interlayer insulating film, the gate interconnection film, and the first interlayer insulating film, forming an exposed insulating film on a part in the inner face of the contact hole where the gate interconnection film is exposed and forming, on the semiconductor substrate, an interconnection film so as to fill the contact hole and be electrically connected to the source region.

Various embodiments will be described hereinafter with reference to the accompanying drawings.

### First Embodiment

An embodiment of the invention will be explained below, referring to the drawings.

A first embodiment will be explained first.

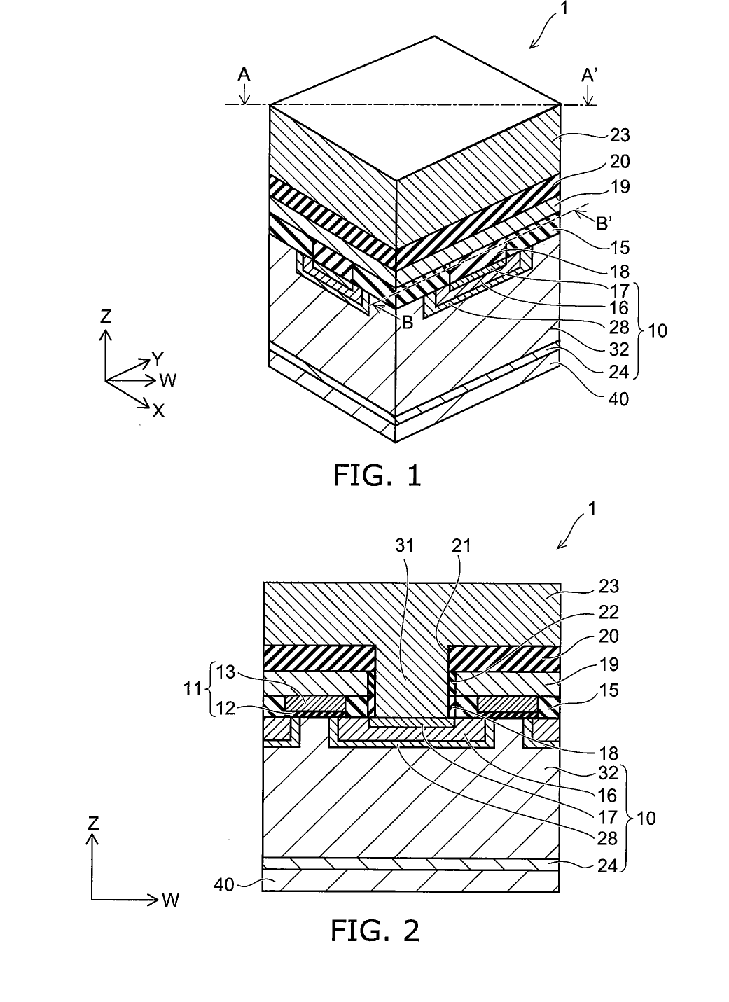

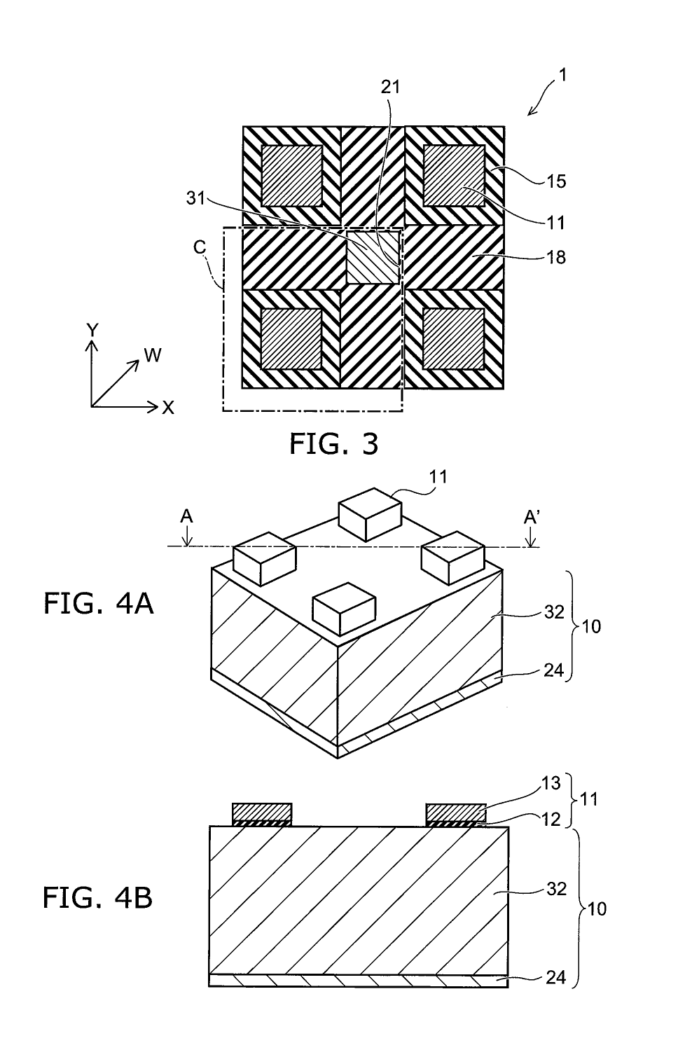

FIG. 1 is a schematic perspective view illustrating a semiconductor device according to the first embodiment, FIG. 2 is a schematic cross-sectional view taken along the A-A′ plane shown in FIG. 1, illustrating the semiconductor device according to the first embodiment, and FIG. 3 is a schematic cross-sectional view taken along the B-B′ plane shown in FIG. 1, illustrating the semiconductor device according to the first embodiment.

As shown in FIGS. 1 to 3, a semiconductor device 1 has a semiconductor substrate, for example, a silicon substrate 10, a gate 11, a side wall insulating film 15, an interlayer film 18, a gate interconnection film 19, an interlayer insulating film 20, an exposed insulating film 22, an interconnection film 23, and a contact 31. The silicon substrate 10 has a drain layer (substrate) 24, a drift region 32, a base 28, a source region 16, and a silicide 17. The gate 11 has a gate oxide film 12 and a gate electrode 13.

First, the positional relation between the silicon substrate 10 and the gate 11 will be explained.

On the silicon substrate 10, a plurality of the gates 11 are provided separately in an island-shaped manner. The gates 11 are quadrangular prism-shaped having square bottom faces and square upper faces.

FIGS. 1 to 3 illustrate the semiconductor device 1 in a cross-sectional manner. Although FIG. 3 illustrates only four of the gates 11, it is not limited. In the actual semiconductor device 1, the illustrated structure is repeated and a number of gates ranging from hundreds of thousands to billions may be provided thereon.

In the following, for convenience of explanation, two directions which are parallel to the upper face of the silicon substrate 10 and perpendicular to each other are referred to as the “X-direction” and “Y-direction”. In addition, a direction which is perpendicular to the upper face of the silicon substrate 10 is referred to as the “Z-direction”. Furthermore, a direction which is parallel to the upper face of the silicon substrate 10 and at an angle of 45 degrees relative to the X- and Y-axes is referred to as the “W-direction”. Additionally, in FIG. 3, the illustrated horizontal direction is defined as the X-direction, and the vertical direction is defined as the Y-direction. As shown in FIG. 3, a plurality of gates 11 are arranged at regular intervals in a direction, for example the X-direction, which is perpendicular to two opposing side faces of the quadrangular prism. With regard to each of the gates 11 arranged at regular intervals in one direction, the gates 11 are arranged in a direction, for example the Y-direction, which is perpendicular to the one direction at regular intervals. Therefore, the gates 11 are arranged on the silicon substrate 10 in a matrix.

Next, the gate 11 will be explained.

The gate 11 has a silicon oxide film 12, for example, as a gate insulating film in its lowermost part. The silicon oxide film 12 is in contact with the silicon substrate 10. The gate electrode 13 is provided on the silicon oxide film 12. The gate electrode 13 is formed by polysilicon having boron and phosphorus doped therein, for example. In the embodiment, the gate 11 includes the silicon oxide film 12 and the gate electrode 13.

Next, the silicon substrate 10 will be explained.

At the lower layer of the silicon substrate 10, a drain layer 24 is provided. The drain layer 24 has phosphorus introduced therein, for example, as an impurity being of n-type.

On the drain layer 24 on the silicon substrate 10, the drift region 32 is provided. The drift region 32 has phosphorus (P) introduced therein, for example, being of n-type. The effective impurity concentration in the drift region 32 is lower than the effective impurity concentration of the drain layer 24. The “effective impurity concentration” in the specification refers to the concentration of impurity contributing to conductivity of the semiconductor material and, if an impurity serving as a donor and an impurity serving as an acceptor are both contained in the semiconductor material, for example, refers to the density of the portion of the activated impurities excluding the offset portion of the donor and the acceptor.

The base 28 is selectively provided on the drift region 32 on the silicon substrate 10. The base 28 has boron introduced therein, for example, as an impurity being of p-type.

On the base 28, the source region 16 is selectively provided. The source region 16 has phosphorus introduced therein as impurities, for example, being of n-type. The source region 16 is provided between regions immediately below the gate 11 on the silicon substrate 10. Viewed from above the silicon substrate 10, therefore, the source region 16 is lattice-shaped. The outer edge of the source region 16 on the upper face of the silicon substrate 10 extends to immediately below the silicon oxide film 12.

In addition, the base 28 is formed so as to cover the lower face and the side face of the source region 16. The outer edge of the base 28 on the upper face of the silicon substrate 10 extends to immediately below the silicon oxide film 12. The base 28 has boron introduced therein as an impurity, for example.

The silicon oxide film 12 on the gate 11 is provided to be in contact with the source region 16, the base 28, and the end of the drift region 32 on the upper face of the silicon substrate 10.

On the lower part of the silicon substrate 10, a drain interconnection film 40 is provided. The drain interconnection film 40 is in contact with the drain region 24.

Next, a configuration of the semiconductor device 1 other than the configuration described above will be explained.

On the four side faces of the gate 11, the side wall insulating film 15 is provided. The side wall insulating film 15 includes a silicon oxide film, for example. The silicide 17 is provided in the region of the upper face of the source region 16 which is not covered by the side wall insulating film 15. The silicide 17 includes, for example, titanium silicide, cobalt silicide, tungsten silicide, and nickel silicide.

Between each of the gates 11 surrounded by the side wall insulating film 15 on the upper face of the silicon substrate 10, the interlayer film 18 is provided. The interlayer film 18 is formed by, for example, a USG (Undope Silicate Glass) film, a BPSG (Boron Phosphorous Silicate Glass) film, a PSG (Phosphorous Silicate Glass) film, and a silicon oxide film. The upper face of the interlayer film 18 corresponds to the upper face of the gate 11 and the side wall insulating film 15.

On the upper face of the gate 11, the side wall insulating film 15, and the interlayer film 18, the gate interconnection film 19 is provided. The gate interconnection film 19 is provided by a conductive material, for example, polysilicon having impurities such as boron or phosphorus added with a high concentration.

The gate interconnection film 19 is a continuous film provided almost all over the semiconductor device 1, and electrically connected in common to the gate electrode 13 provided at the upper part of the gate 11. The interlayer insulating film 20 is provided on the gate interconnection film 19. The interlayer insulating film 20 is formed by a USG film, for example.

In the interlayer film 18, the gate interconnection film 19 and the interlayer insulating film 20, a contact hole 21 is provided in a region immediately above the crossover region of the lattice constituting the lattice-shaped source region 16. The exposed insulating film 22 is provided on a part corresponding to the gate interconnection film 19 in the inner wall face of the contact hole 21. The exposed oxidation film 22 is formed by a silicon oxide film, for example.

On the interlayer insulating film 20, an interconnection film 23 is provided so as to fill the contact hole 21. The interconnection film 23 is formed by an aluminum film, for example. The interconnection film 23 is a continuous film provided almost all over the semiconductor device 1, having a film thickness thicker than the film thickness of the gate interconnection film 19. The part of the interconnection film 23 filling the contact hole 21 will become the contact 31. The contact 31 is electrically joined to the silicide 17. In contrast, the contact 31 is insulated from the gate interconnection film 19 by the exposed insulating film 22. In addition, the contact 31 is insulated from the gate electrode 13 by the interlayer film 18.

The contact 31 is provided on the source region 16 surrounded by four of the gates 11, i.e., on a region immediately above the crossover region of the lattice constituting the lattice-shaped source region 16. This is preferable in terms of unifying the resistance and dimensional allowance of the silicide 17. However, the position of forming the contact 31 is not limited to the above. The contact may be provided between the gates 11 with the side faces facing each other.

On the lower face of the silicon substrate 10, the drain interconnection film 40 is provided. The drain interconnection film 40 is in contact with the drain region 24.

In the semiconductor device 1 according to the embodiment described above, electric potential of the negative terminal is applied to the source interconnection film 23 of the semiconductor device 1, whereas electric potential of the positive terminal is applied to the drain interconnection film 40. The negative electric potential applied to the source interconnection film 23 is applied to the source region 16 via the contact 31 and the silicide 17. In contrast, the positive electric potential applied to the drain interconnection film 40 is applied to the drain layer 24 and the drift region 32. At this time, if a predetermined electric potential is not applied to the gate interconnection film 19, a depletion layer extends from the interface between the p-type base 28 of and the n-type drift region 32. Accordingly, no electric current flows between the drain interconnection film 40 and the source interconnection film 23.

In this state, applying gate potential of the positive terminal to the gate interconnection film 19 causes the gate potential to be applied to a plurality of gate electrodes 13. Accordingly, the silicon oxide film 12 serves as a gate insulating film, whereby an inverted layer is provided on a part contacting the silicon oxide film 12 on the base 28. Movement of the carrier in the inverted layer causes electronic current to flow through a path of the source interconnection film 23, the contact 31, the silicide 17, the source region 16, the base 28 (inverted layer), the drift region 32, the drain layer 24, and the drain interconnection film 40. The amount of current flowing between the source and the drain is then controlled by controlling the gate potential applied to the gate interconnection film 19.

A manufacturing method of the embodiment will be explained below.

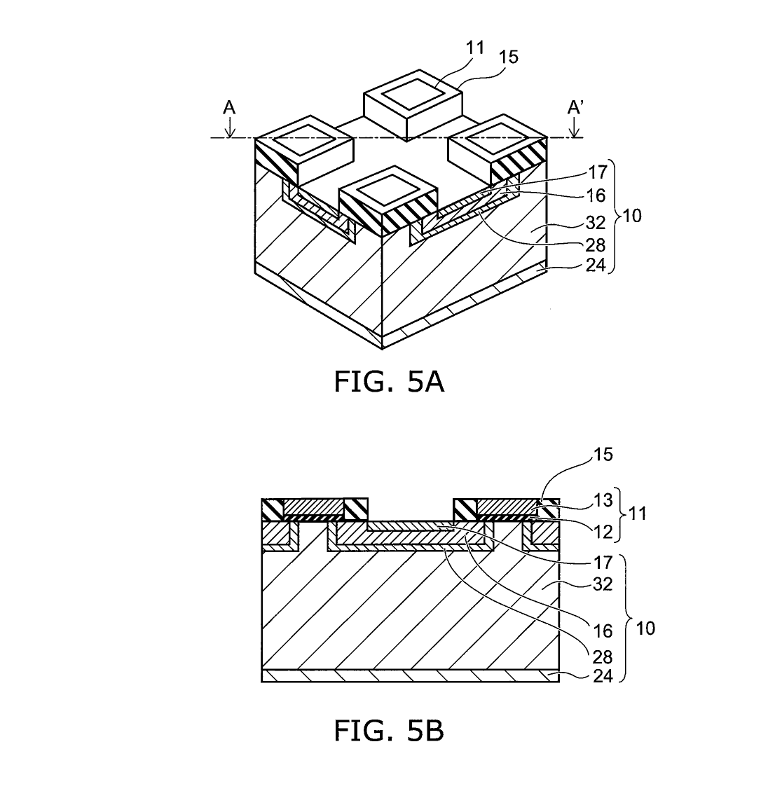

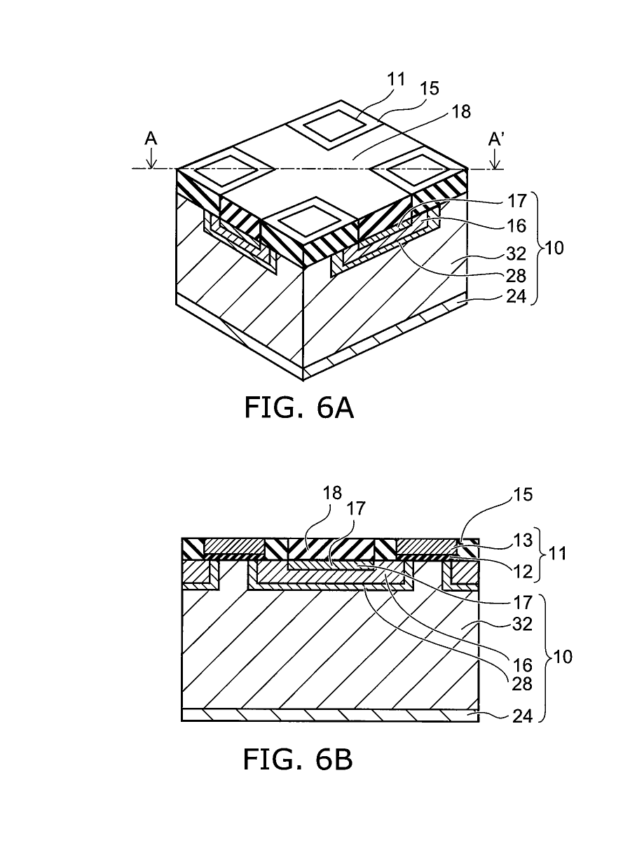

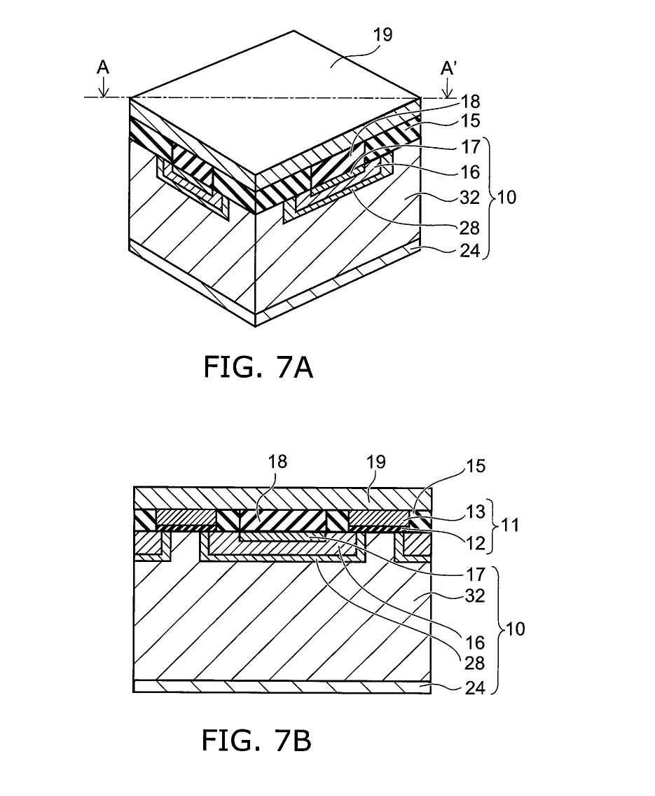

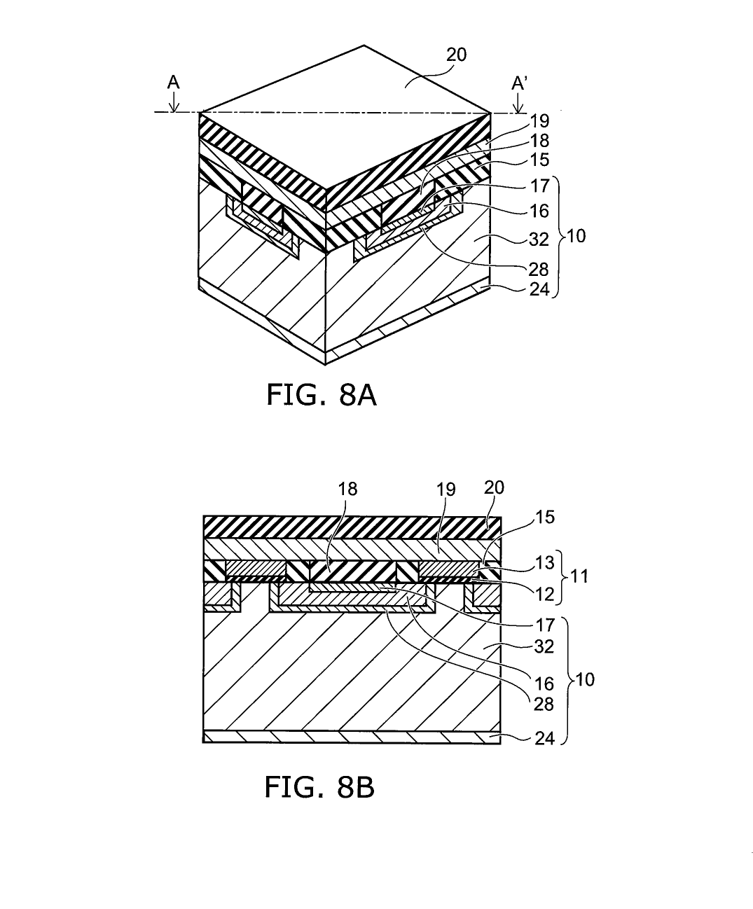

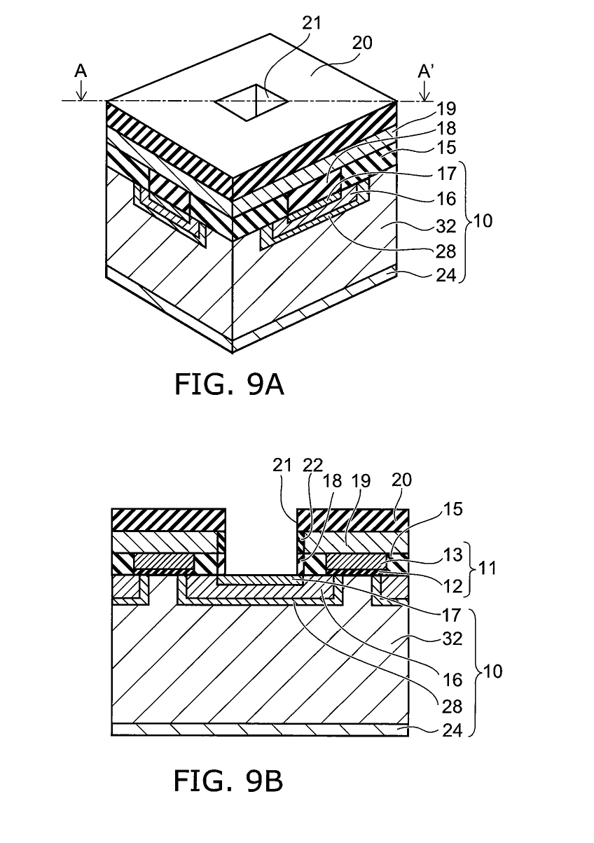

FIG. 4A, FIG. 5A, FIG. 6A, FIG. 7A, FIG. 8A and FIG. 9A are schematic perspective views illustrating the method for manufacturing the semiconductor device according to the first embodiment, FIG. 4B, FIG. 5B, FIG. 6B, FIG. 7B, FIG. 8B and FIG. 9B are schematic perspective views taken along the A-A′ plane shown in FIG. 4A, FIG. 5A, FIG. 6A, FIG. 7A, FIG. 8A and FIG. 9A, respectively, illustrating the method for manufacturing the semiconductor device according to the first embodiment.

First, as shown in FIGS. 4A and 4B, the silicon substrate 10 made of, for example, single crystal silicon (Si) is prepared. The silicon substrate 10 has an n-type drift layer 32 having phosphorus or the like introduced therein formed on an n-type drain layer (substrate) 24 having phosphorus or the like introduced therein. The effective impurity concentration of the drain layer is assumed to be higher than the effective impurity concentration of the drift layer.

Next, the silicon oxide film 12, for example, is formed on the upper face of the silicon substrate 10 as a gate insulating film. Subsequently, a polysilicon film serving as the gate electrode 13 is formed on the silicon oxide film 12. Next, a hard mask is formed on the polysilicon. The hard mask is formed by forming a silicon nitride film on the polysilicon film and subsequently patterning the silicon nitride film using lithography.

A plurality of hard masks are formed, each being square-shaped when viewed from above. The plurality of hard masks are arranged at regular intervals in one direction perpendicular to two opposing side faces of the square, and also arranged at regular intervals in a direction perpendicular to the one direction in each of the hard masks arranged at regular intervals in one direction.

Next, the polysilicon film and the silicon oxide film 12 are selectively removed, using the hard mask as a mask. Accordingly, the gate 11 including the silicon oxide film 12 and the gate electrode 13 is formed. A plurality of gates 11 are formed, each being quadrangular prism-shaped. The plurality of gates 11 are arranged at regular intervals in one direction perpendicular to two opposing side faces of the quadrangular prism, and also arranged at regular intervals in a direction perpendicular to the one direction in each of the gates 11 arranged at regular intervals in one direction.

Next, as shown in FIGS. 5A and 5B, boron is ion-injected into the silicon substrate 10 using the gate 11 as a mask. Subsequently, by heat treatment, the base 28 is formed between regions immediately below the gate 11 on the silicon substrate 10 so that the outer edge of the base 28 on the upper face of the silicon substrate 10 expands to immediately below the silicon oxide film 12.

Subsequently, the side wall insulating film 15 is formed on the four side faces of the gate 11. The side wall insulating film 15 is formed by removing the part other than the side face s of the gate 11, after the silicon oxide film has been formed on the silicon substrate 10.

Next, phosphorus is ion-injected into the silicon substrate 10 by using the gate 11 and the side wall insulating film 15 as a mask. Subsequently, the injected phosphorus is dispersed to immediately below the silicon oxide film 12 on the upper face of the silicon substrate 10 by heat treatment. As a result, the source region 16 is formed at the end the region immediately below and between regions immediately below the gate 11 at the upper part of the base 28. Accordingly, the silicon oxide film 12 is provided with a structure being in contact with the end of the source region 16, the base 28, and the drift region 32 on the upper face of the silicon substrate 10. A part of the base 28 contacting with the silicon oxide film 12 becomes a channel. The source region 16 is lattice-shaped when viewed from above the silicon substrate 10.

Subsequently, the face of the source region 16 is silicided by heating after depositing a metal film, for example, titanium on the silicon substrate 10. Next, titanium which has not reacted is removed. Accordingly, the silicide 17 is formed on the face of the source region 16 to reduce the resistance.

Here, other than titanium, the metal film may be formed with, cobalt, tungsten, nickel or the like. When forming the metal film with nickel, the condition of heat treatment for bringing the polysilicon film and nickel into silicidation reaction may be adjusted to perform silicidation of the upper face of the gate electrode 13. Accordingly, the resistance of the gate electrode 13 can be reduced.

Subsequently, as shown in FIGS. 6A and 6B, the interlayer film 18 is formed between each of the gates 11 surrounded by the side wall insulating film 15 on the silicon substrate 10. As the interlayer film 18, for example, a BPSG film, a PSG film, or a USG film are formed. After these films have been coated on the silicon substrate 10, the interlayer film 18 is formed by polishing until the upper face of the gate 11 is exposed.

Next, as shown in FIGS. 7A and 7B, the gate interconnection film 19 is formed on the upper face of the gate 11 and the interlayer film 18. The gate interconnection film 19 is electrically connected to the upper face of the gate electrode 13 which is exposed to the upper face of the gate 11. As the gate interconnection film 19, for example, a polysilicon film is formed.

Subsequently, as shown in FIGS. 8A and 8B, the interlayer insulating film 20 is provided on the gate interconnection film 19. As the interlayer insulating film 20, for example, a USG film is formed.

Then, in the interlayer insulating film 20, the gate interconnection film 19, and the interlayer film 18, as shown in FIGS. 9A and 9B, the contact hole 21 is provided in a region immediately above the crossover region of the lattice constituting the lattice-shaped source region 16. The contact hole 21 is provided so as to reach the silicide 17. The contact hole 21 is provided by selectively removing the interlayer insulating film 20, the gate interconnection film 19, and the interlayer film 18, using the resist formed on the interlayer insulating film 20 as a mask.

Next, the gate interconnection film 19 exposed on the inner wall face of the contact hole 21 is oxidized to form the exposed insulating film 22. Since the gate interconnection film 19 is a polysilicon film, it has a faster oxidation speed than the silicon substrate 10. Furthermore, the gate interconnection film 19 includes impurities such as boron or phosphorus with a high concentration, which also contributes to increase the oxidation speed. Here, the exposed insulating film 22 may be formed not only by oxidation of the gate interconnection film 19, but also by embedding the insulating film by CVD, for example.

Subsequently, a conductive film, for example, an aluminum film is formed on the silicon substrate 10 so as to fill the contact hole 21 to form the interconnection film 23. A part inside the contact hole 21 on the interconnection film 23 becomes the contact 31. The contact 31 is electrically connected to the silicide 17 formed at the upper layer of the source region 16. In contrast, the contact 31 is insulated from the gate interconnection film 19 by the exposed insulating film 22. In addition, the contact 31 is insulated from the gate electrode 13 by the interlayer film 18.

In this manner, the semiconductor device 1 is manufactured as shown in FIGS. 1 to 3.

According to the embodiment, since the gate electrode 13 is island-shaped when viewed from above, the ratio of the region occupying the upper face of the silicon substrate 10 of the source region 16 supposed to be the current pathway can be made larger than stripe and mesh shapes.

For example, as shown in FIG. 3, the ratio occupied by the source region 16 on the upper face of the silicon substrate 10 is 75%, based on the basic unit shown in region C.

Accordingly, the area of the current pathway can be made wider. Therefore, since RonA can be reduced even if the device structure is miniaturized, higher integration of semiconductor device can be realized.

In addition, according to the embodiment, forming the gate interconnection film 19 on the gate 11 and the side wall insulating film 15 in a layered manner allows the gate interconnection film 19 to be connected in common to a plurality of gate electrodes 13 in a self-aligned manner, as well as maintaining insulation from other source interconnection films and impurity regions. Accordingly, lithography is not required because the gate interconnection film 19 is not subjected to patterning. Therefore, higher integration can be realized without depending on the precision of lithography.

In addition, a complicated and expensive process such as multilayer interconnection technology is not required. Therefore, manufacturing time of a semiconductor device can be shortened, as well as reducing manufacturing cost.

Other effects of the embodiment besides those described above are similar to the aforementioned first embodiment.

### Second Embodiment

Next, a second embodiment will be explained.

The embodiment relates to a semiconductor device having a trench gate structure.

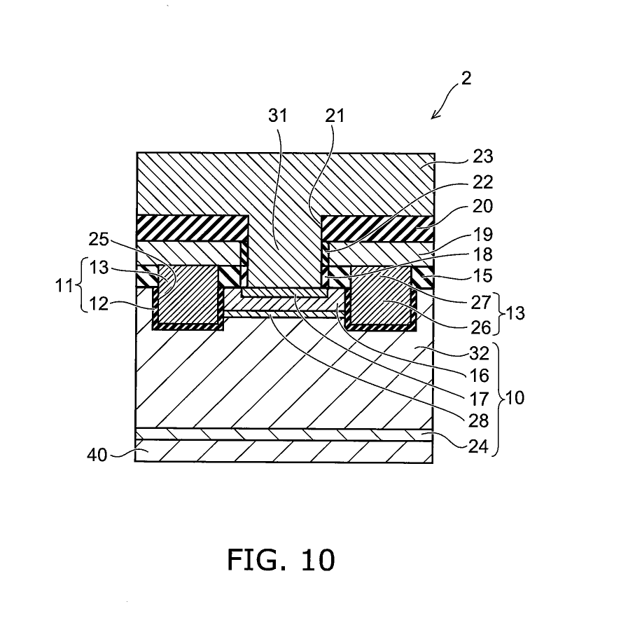

FIG. 10 is a schematic cross-sectional view illustrating a semiconductor device according to the second embodiment.

As shown in FIG. 10, the semiconductor device 2 has a semiconductor substrate, for example, the silicon substrate 10, the gate 11, the side wall insulating film 15, the interlayer film 18, the gate interconnection film 19, the interlayer insulating film 20, the exposed insulating film 22, the interconnection film 23, and the contact 31. The silicon substrate 10 has the drain layer (substrate) 24, the drift layer 32, the base 28, the source region 16, and the silicide 17. The gate 11 has the gate oxide film 12 and the gate electrode 13.

First, the gate 11 will be explained.

The silicon substrate 10 is provided with a hole 25 opening on the upper face. The shape of the hole 25 when viewed from above corresponds to the shape of the bottom face of the gate 11. For example, if the shape of the gate 11 is quadrangular prism, the shape of the hole 25 when viewed from above is square.

On the inner face of the hole 25, the silicon oxide film 12 is provided as gate insulating film, for example. A part of the gate electrode 13 is embedded inside the hole 25. The part of the gate electrode 13 embedded in the hole 25 is referred to as a lower gate electrode 26, and the part of the gate electrode 13 on the upper face of the silicon substrate 10 is referred to as an upper gate electrode 27. The gate 11 is made of the upper gate electrode 27. Therefore, the gate 11 includes at least a part of the gate electrode 13 provided on the silicon substrate 10.

Next, the silicon substrate 10 will be explained.

The hole 25 is provided so as to reach the drift region 32 on the silicon substrate 10. The base 28 is provided between each of the holes 25 on the drift region 32. The source region 16 is provided between each of the holes 25 on the base 28. Also in the embodiment, the source region 16 is lattice-shaped when viewed from above the silicon substrate 10. Therefore, the hole 25 is formed in a manner penetrating the source region 16 and the base 28 so as to reach the drift region.

On the inner face of the hole 25, the source region 16, the base 28, and the drift region 32 are in contact with the silicon oxide film 12 of the gate 11.

On the side face of the gate 11, i.e., the upper gate electrode 27, the side wall insulating film 15 is provided. The base 28 is formed to be shallower than the hole 25. The source region 16 is formed to be shallower than the base 28. The configuration of other elements is similar to the aforementioned first embodiment.

In the following, a manufacturing method of a semiconductor device according to the embodiment will be explained.

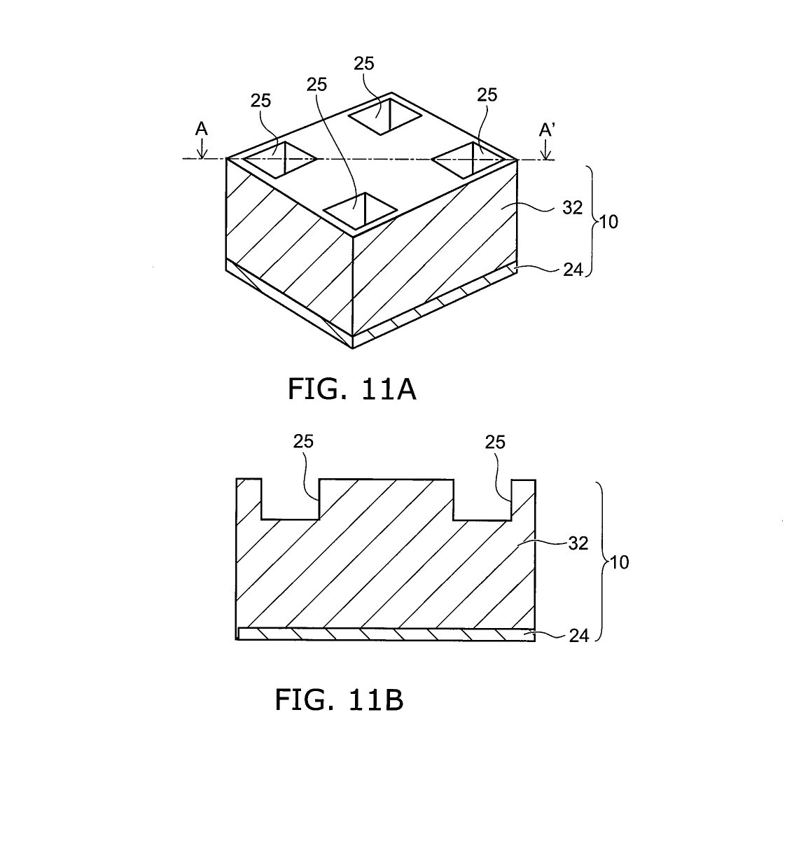

FIG. 11A is a schematic perspective view illustrating the method for manufacturing the semiconductor device according to the second embodiment, and FIG. 11B is a schematic process cross-sectional view taken along the A-A′ plane shown in FIG. 11A, illustrating the method for manufacturing the semiconductor device according to the second embodiment.

As shown in FIGS. 11A and 11A, the hole 25 is formed on the silicon substrate 10.

Subsequently, the silicon oxide film 12, for example, is formed on the inner face of the hole 25 as a gate insulating film. The silicon oxide film 12 is formed by removing the part other than the part on the inner face of the hole 25, after the silicon oxide film 12 has been formed on the silicon substrate including the inner face of the hole 25.

Next, a polysilicon film is provided on the silicon substrate 10 so as to fill the hole 25. Subsequently, a part of the polysilicon film other than the part arranged inside the hole 25 and in a region immediately above the hole 25 is removed to form the gate electrode 13. The gate electrode 13 is made of a part inside the hole 25 and a part on the upper face of the silicon substrate 10. The part inside the hole 25 is referred to as the lower gate electrode 26, and the part on the upper face of the silicon substrate 10 is referred to as the upper gate electrode 27. In the embodiment, the gate 11 is made of the upper gate electrode 27. Therefore, the gate 11 includes a part of the gate electrode 13.

Next, the side wall insulating film 15 is formed on the gate 11, i.e. the side wall around the upper gate electrode 27.

Subsequently, the base 28 is formed on the upper layer part of the silicon substrate 10. The base 28 is formed so as to be located at a layer higher than the bottom face of the hole 25.

Next, the source region 16 is formed on the upper part of the base 28.

The part other than the source region 16, the base 28, and the drain layer 24 on the silicon substrate 10 becomes the drift region 32.

The silicon oxide film 12 formed on the inner face of the hole 25 is in contact with the end of the source region 16, the base 28, and the drift region 32.

The manufacturing method other than the method described above in the embodiment is similar to the aforementioned first embodiment.

### COMPARATIVE EXAMPLE 1

Next, a comparative example 1 will be explained.

In the comparative example, a stripe-shaped gate electrode 35 is provided instead of the quadrangular prism-shaped gate electrode 13 (see FIG. 1 etc.) arranged in an island-shaped manner.

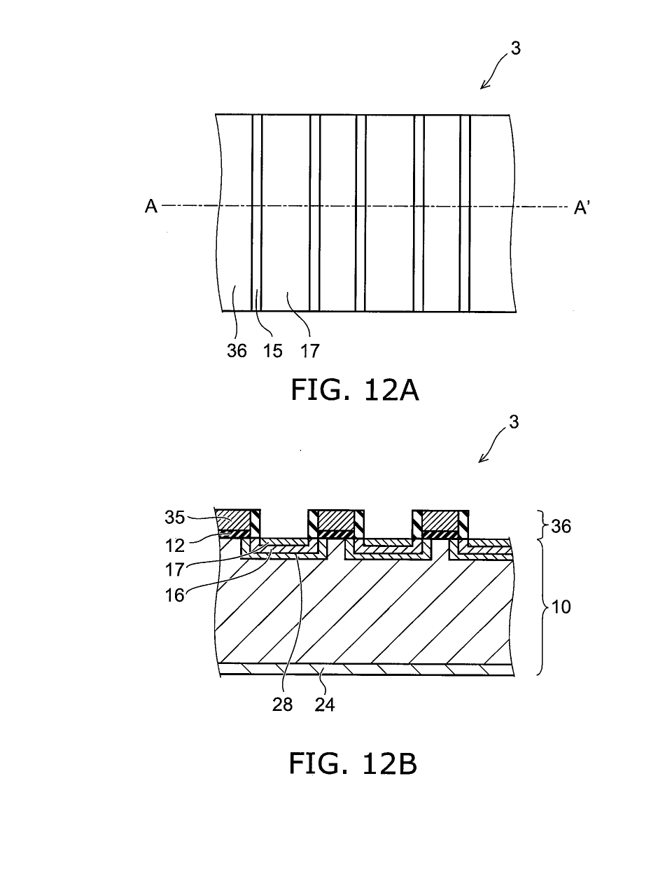

FIGS. 12A and 12B are schematic planar views illustrating a semiconductor device according to the comparative example 1, in which FIG. 12B is a schematic cross-sectional view taken along the A-A′ plane shown in FIG. 12A.

As shown in FIGS. 12A and 12B, in the semiconductor device 3 according to the comparative example 1, on the silicon substrate 10, a plurality of gates 36 of extending in parallel to each other are provided. The side wall insulating film 15 is provided on the side face of the gate 36. As a gate insulating film, the silicon oxide film 12, for example, is provided in the lowermost part of the gate 36. The gate electrode 35 is provided on the silicon oxide film 12 so as to be in contact with the silicon oxide film 12. The source region 16 is formed between the regions immediately below the gate 36 on the silicon substrate 10. Therefore, the shape of the source region 16 is also stripe-shaped when viewed from above. The silicide 17 is formed on the upper face of the source region 16.

In a low withstand voltage MOS device, electric current between the source and drain is controlled by a single gate signal. Therefore, the gate electrode 13 having a stripe structure as in the comparative example makes it easier to bundle the gate signals.

However, if the gate electrode 13 and the source region 16 are stripe-structured as described above, the ratio of the region occupied by the source region 16 on the upper face of the silicon substrate 10 is about 50%. Therefore, the ratio becomes lower than the ratio of about 75% occupied by the source region 16 of the semiconductor device 1 according to the first embodiment.

### COMPARATIVE EXAMPLE 2

Next, a comparative example 2 will be explained.

The comparative example is about a semiconductor device 4 having formed a gate interconnection layer 29 and an interconnection layer 30 formed thereon by using lithography.

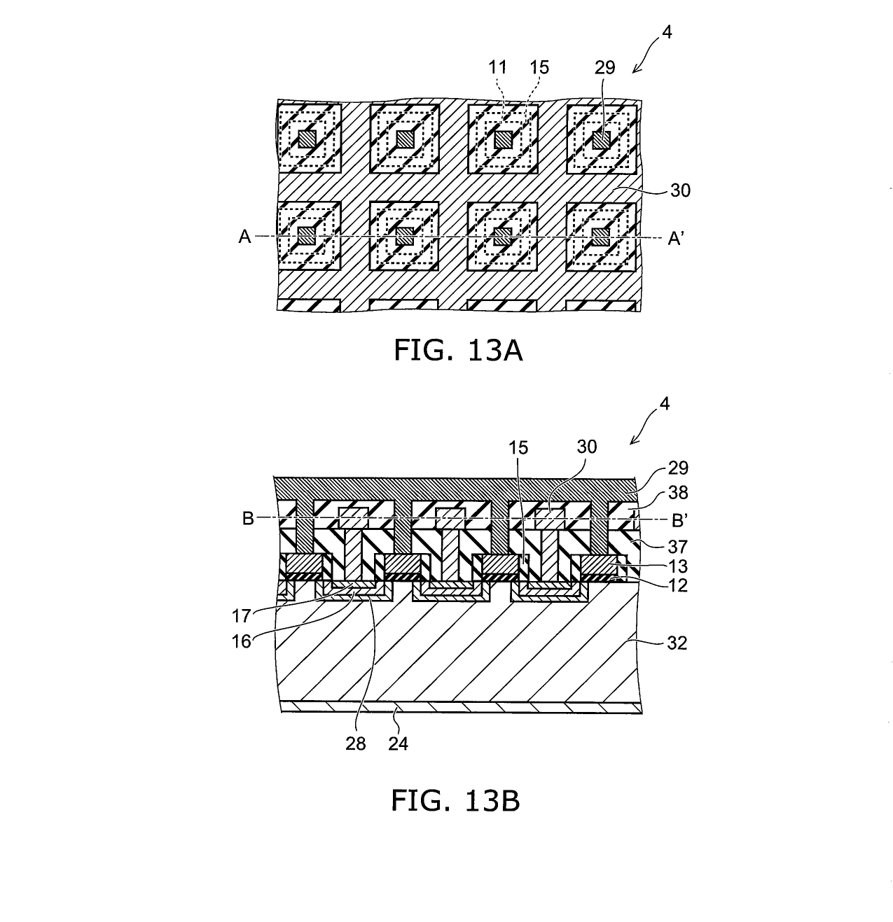

FIGS. 13A and 13B are schematic cross-sectional views illustrating a semiconductor device according to the comparative example 2, in which FIG. 13B is a schematic cross-sectional view taken along the A-A′ plane shown in FIG. 13A. In addition, FIG. 13A is a schematic cross-sectional taken along the B-B′ plane shown in FIG. 13B.

As shown in FIGS. 13A and 13B, in the semiconductor device 4 according to the comparative example 2, a plurality of gates 11 are separately provided on the silicon substrate 10 in an island-shaped manner. As a gate insulating film, the silicon oxide film 12, for example, is provided in the lowermost part of the gate 11. The gate electrode 13 is provided on the silicon oxide film 12 to be in contact with the silicon oxide film 12. The source region 16 and the base 28 are formed between the regions immediately below the gate 11 on the silicon substrate 10. In addition, the drain layer 24 is formed so as to be exposed to the back side of the silicon substrate 10 at the bottom of the silicon substrate 10.

In order to simultaneously apply a common electric potential to the source region 16 formed on the upper face of the silicon substrate 10 in a lattice-shaped manner, a source interconnection layer 30 is formed immediately above the source region 16 in a lattice-shaped manner. Such a source interconnection layer 30 is formed as follows. That is, after having formed an interlayer insulating film 37 on the silicon substrate 10 so as to cover the gate 11, a contact hole is formed on the interlayer insulating film 37. Subsequently, a metal layer is formed so as to fill the contact hole, and the metal layer is subjected to patterning by lithography. In this manner, the source interconnection layer 30 is formed.

Additionally, in order to simultaneously apply a common electric potential to the gate electrode 13 formed in an island-shaped manner, a gate interconnection 29 connected in common to the gate electrode 13 is formed. Such a gate interconnection layer 29 is formed as follows. That is, after having formed an interlayer insulating film 38 on the silicon substrate 10 so as to cover the source interconnection layer 30, a contact hole is formed so as to avoid the interconnection in the source interconnection layer 30 on the interlayer insulating films 37 and 38. Subsequently, a metal film is provided so as to fill the contact hole, and the metal layer is subjected to patterning by lithography. In this manner, the gate interconnection layer 30 is provided.

As described above, the ratio of the region occupied by the source region 16 on the upper face of the silicon substrate 10 becomes about 50% in the comparative example 1.

Therefore, in the comparative example 2 as shown in FIGS. 13A and 13B, the gate electrode 13 is arranged in an island-shaped manner, around which the source interconnection layer 30 is arranged.

In the comparative example 2, the ratio of the region occupied by the source region 16 on the upper face of the silicon substrate 10 is about 75%, which has improved compared with the stripe structure.

However, in the comparative example 2, both the gate interconnection layer 29 which collectively bundles the gate electrodes 13 and the source interconnection layer 30 for discharging the electric current to the outside the source electrode are subjected to patterning by lithography. Therefore, an expensive process which makes use of two or more metal interconnection layers of the gate interconnection layer 29 and the source interconnection layer 30 is required.

A complicated and expensive process such as the multilayer interconnection technology takes a long manufacturing time and prevents miniaturization due to the overuse of lithography.

In contrast, in the embodiment, a part of the trench gate structure, i.e., gate electrode 13 is embedded in the hole 25 provided on the silicon substrate 10. The gate insulating film 12 is then provided on the inner face of the hole. Therefore, a channel is provided along the inner face of the hole 25. The direction of current flowing in the channel is oriented toward the thickness direction of the silicon substrate 10.

In addition, the degree of integration of the transistor on the wafer surface can be increased by providing a trench gate structure and orienting the current pathway in the channel toward the thickness direction of the wafer.

### Third Embodiment

Next, a third embodiment will be explained.

The embodiment assumes that the shape of a gate 33 is a hexagonal prism instead of a quadrangular prism.

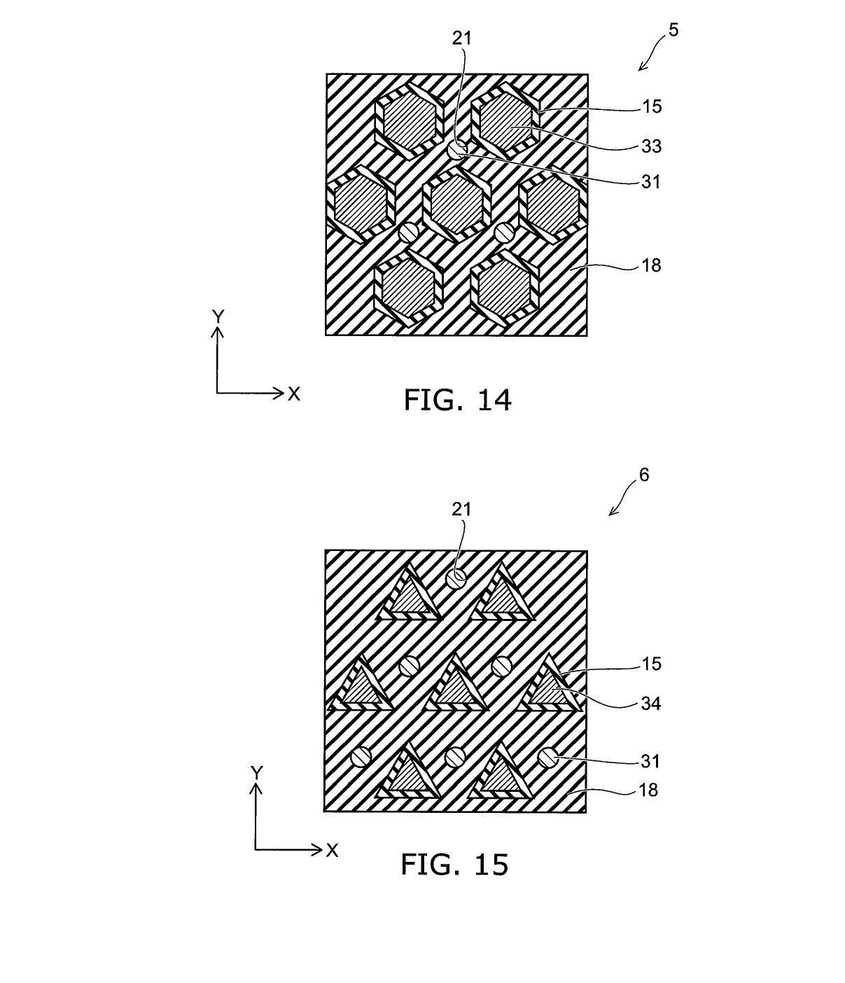

FIG. 14 is a schematic cross-sectional view illustrating a semiconductor device according to the third embodiment.

As shown in FIG. 14, gate 33 is hexagonal prism-shaped in a semiconductor device 5 according to the embodiment. Here, the horizontal and the vertical directions in FIG. 5 are defined as the X- and the Y-directions for convenience.

As shown in FIG. 14, the hexagonal prism-shaped gates 33 are arranged at regular intervals in a direction perpendicular to two opposing side faces of the hexagonal prism, for example, along the X-direction. In addition, the gates 33 are arranged at regular intervals in one of the directions perpendicular to the remaining two sets of two opposing side faces, for example, a direction inclined against the X-axis counterclockwise by an angle of 60° when viewed from above. In such a case, the gates 33 are also arranged at regular intervals in the other direction, i.e., the direction inclined against the X-axis counterclockwise by an angle of 120°.

Also when the side wall insulating film 15 is formed around the gate 33, the overall shape made of the gate 33 and the side wall insulating film 15 is assumed to be a hexagonal prism. The contact hole 21 is formed at an intermediate position among three of the gates 33.

According to the embodiment, the gate 33 is hexagonal prism-shaped, and thus the angle formed by adjacent side faces of the gate electrode 13 is 120°, which is larger than the angle of 90° formed by adjacent side faces of the quadrangular prism-shaped gate electrode 13. Accordingly, electric field concentration at the end of the gate electrode 13 can be mitigated. Therefore, it is not necessary to widen the space of the gate electrode 13 in order to mitigate the electric field concentration, whereby degree of integration of the semiconductor device 5 can be increased.

### Fourth Embodiment

Next, a fourth embodiment will be explained.

The embodiment assumes that the shape of a gate 34 is a triangular prism.

FIG. 15 is a schematic cross-sectional view illustrating a semiconductor device according to the fourth embodiment.

As shown in FIG. 15, the gate 34 is assumed to be triangular prism-shaped in a semiconductor device 6 according to the embodiment. Here, like in the case of the explanation of the aforementioned embodiment, the horizontal and the vertical directions in FIG. 15 are defined as the X- and the Y-directions.

As shown in FIG. 15, the equilateral triangular gates 34 are arranged at regular intervals in a direction parallel to one of the side faces of the triangular prisms, for example, along the X-direction. In addition, the gates 34 are arranged at regular intervals in one of the directions parallel to the remaining two side faces, for example, a direction inclined against the X-axis counterclockwise by an angle of 60°. In such a case, the gates 34 are also arranged at regular intervals in the other direction, i.e., the direction inclined against the X-axis counterclockwise by an angle of 120°.

Also when the side wall insulating film 15 is provided around the gate 34, the overall shape of the gate 34 and the side wall insulating film 15 is set to be a triangular prism. The contact hole 21 is formed at an intermediate position among three of the gates 34.

According to the embodiment, by setting the shape of the gate 34 to triangular prism, the area of the source region 16 can be made larger. Therefore, RonA can be reduced, whereby a higher integration of the semiconductor device 6 can be realized.

### Fifth Embodiment

Next, a fifth embodiment will be explained.

The embodiment assumes that the arrangement of the gate 11 is offset meshed.

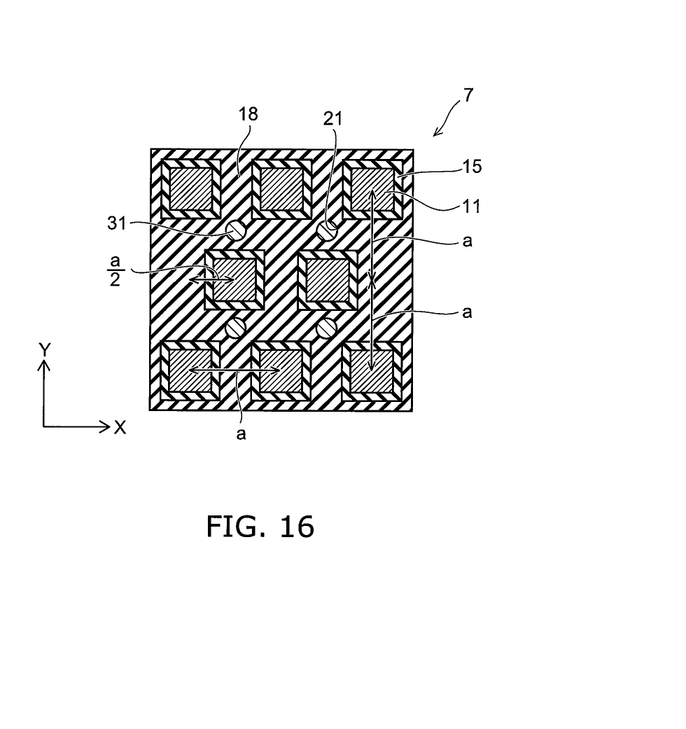

FIG. 16 is a schematic cross-sectional view illustrating a semiconductor device according to the fifth embodiment.

As shown in FIG. 16, the gate 11 is assumed to be quadrangular prism-shaped in a semiconductor device 7 according to the embodiment. Here, like in the case of the explanation of the aforementioned embodiment, the horizontal and the vertical directions in FIG. 16 are defined as the X- and the Y-directions.

As shown in FIG. 16, the quadrangular prism-shaped gates 11 are arranged with an array period a in a direction perpendicular to two opposing side faces of the quadrangular prism, for example, in the X-direction.

As thus described, a group made of a plurality of gates 11 aligned at regular intervals along the X-directions is referred to as a “column”. A plurality of such columns are arranged with an array period a in a direction perpendicular to the other two opposing side faces of the quadrangular prism, for example, the Y-direction. Additionally, in the X-direction, the position of one of the gates 11 in one column is shifted by half the array period a (a/2) relative to the position of the gate 11 in its adjacent column. In other words, the phase of the array of the gates 11 is shifted by a half period between two adjacent columns. The contact hole 21 is formed an intermediate position among a total of three gates 11, namely, two mutually adjacent gates 11 belonging to one column and one gate 11 belonging to an adjacent column and positioned between these two gates 11 in the X-direction.

For example, in the first embodiment, although the contact 31 has been formed on the source region 16 surrounded by four of the gates 11, the position of the contact 31 is not limited thereto, as long as the contact 31 is connected to the source region 16. The contact 31 may be connected to the source region 16 corresponding to the center of a region created from six of the gates 11.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a drain layer of a first conductivity type;
a drift region of the first conductivity type provided on the drain layer and having an effective impurity concentration lower than the effective impurity concentration of the drain layer;
a base of a second conductivity type provided on the drift region;
a source region of the first conductivity type provided on the base;
a plurality of gates provided on the drift region, the base, and the source region, and arranged in a manner spaced apart from each other;
a first interlayer insulating film arranged between the plurality of gates on the source region;
a gate interconnection film provided on the first interlayer insulating film and the gate;
a second interlayer insulating film provided on the gate interconnection film;
an interconnection film provided on the second interlayer insulating film and connected in common to the source region, the interconnection film filling the contact hole formed between each of the gates in the second interlayer insulating film, the gate interconnection film and the first interlayer insulating film; and
an insulating film arranged between the gate interconnection film and the interconnection film in the contact hole, wherein
the gate has
a gate electrode; and
a gate insulating film arranged between the gate electrode, and the drift region, the base and the source region, and wherein
the gate interconnection film is electrically connected in common to the gate electrode of the plurality of gates, and
the gate electrode and the gate interconnection film are insulated from the interconnection film inside the contact hole by the first interlayer insulating film and the insulating film.

2. The device according to claim 1, wherein the gate interconnection film and the gate electrode are made of silicon.

3. The device according to claim 1, wherein the shape of the gate is a quadrangular prism.

4. The device according to claim 3, wherein the plurality of gates are arranged at regular intervals in a direction perpendicular to two opposing side faces of the quadrangular prism, and arranged at regular intervals in a direction perpendicular to the other two opposing side faces.

5. The device according to claim 3, wherein the plurality of gates are arranged so that a plurality of columns made of a set of gates are aligned periodically along a direction perpendicular to two opposing side faces of the quadrangular prism,
the plurality of columns are arranged periodically along a direction perpendicular to the other two side faces of the quadrangular prism, and
the position of the gates in one of the columns is shifted by half the array period of the gate in the column relative to the position of a gate in the column adjacent to the one column.

6. The device according to claim 1, wherein the shape of the gate is a hexagonal prism.

7. The device according to claim 6, wherein the plurality of gates are arranged at regular intervals in a direction perpendicular to two opposing side faces of the hexagonal prism, and arranged at regular intervals in a direction perpendicular to the other two opposing sides faces.

8. The device according to claim 1, wherein the shape of the gate is a triangular prism.

9. The device according to claim 8, wherein the plurality of gates are arranged at regular intervals in a direction parallel to a side face of the triangular prism, and arranged at regular intervals in a direction parallel to the other side faces.

10. The device according to claim 1, wherein
the source region, the base, the drift region, and the drain layer are made of silicon, and
the device further having silicide provided on the upper face of the source region.

11. The device according to claim 1, wherein the insulating film contains oxide of elements contained in the gate interconnection film.

12. The device according to claim 1, wherein
the shape of the source region formed between regions immediately below the gate is lattice-shaped when viewed from above, and
the part arranged inside the contact hole in the interconnection film is connected to the source region in a crossover region of a lattice constituting the lattice shape.

13. A semiconductor device comprising:
a drain layer of a first conductivity type;
a drift region of the first conductivity type provided on the drain layer and having an effective impurity concentration lower than the effective impurity concentration of the drain layer;
a base of a second conductivity type provided on the drift region;
a source region of the first conductivity type provided on the base;
a plurality of gates provided inside a plurality of holes penetrating the source region and the base to reach the drift region, a part of the gates being provided on the source region and arranged in a manner spaced apart from each other;
a first interlayer insulating film arranged between the plurality of gates on the source region;
a gate interconnection film provided on the first interlayer insulating film and the gate;
a second interlayer insulating film provided on the gate interconnection film;
an interconnection film provided on the second interlayer insulating film and connected in common to the source region, the interconnection film filling the contact hole formed between each of the gates in the second interlayer insulating film, the gate interconnection film and the first interlayer insulating film; and
an insulating film arranged between the gate interconnection film and the interconnection film in the contact hole, wherein
the gate has
a gate electrode; and
a gate insulating film arranged between the gate electrode, and the drift region, the base and the source region, and wherein
the gate interconnection film is electrically connected in common to the gate electrode of the plurality of gates, and
the gate electrode and the gate interconnection film are insulated from the interconnection film inside the contact hole by the first interlayer insulating film and the insulating film.

14. A method for manufacturing semiconductor device comprising processes of:
forming an insulating film on a semiconductor substrate having formed, on a drain layer of a first conductivity type, a drift region of the first conductivity type having an effective impurity concentration lower than the effective impurity concentration of the drain layer;
forming a conductive film on the insulating film;
etching the conductive film and the insulating film to form, on the semiconductor substrate, a plurality of gates including a gate electrode made of the conductive film and a gate insulating film made of the insulating film;
introducing impurities into an upper layer part of the semiconductor substrate using the plurality of gates as a mask to form a base of the second conductivity type;
forming a side wall insulating film all over the side face of each the gates;
introducing impurities into an upper layer part of the base using the plurality of gates and the side wall insulating film as a mask to form a source region of the first conductivity type;
forming a first interlayer insulating film on the semiconductor substrate to fill the space between the plurality of gates;
forming, on the plurality of gates, the side wall insulating film, and the first interlayer insulating film, a gate interconnection film electrically connected to the gate electrode exposed on the upper faces of the plurality of gates;
forming a second interlayer insulating film on the gate interconnection film;
forming a contact hole reaching the source region on the second interlayer insulating film, the gate interconnection film, and the first interlayer insulating film;
forming an exposed insulating film on a part in the inner face of the contact hole where the gate interconnection film is exposed; and
forming, on the semiconductor substrate, an interconnection film so as to fill the contact hole and be electrically connected to the source region.

15. The method according to claim 14,
using the semiconductor substrate as a silicon substrate, and
further comprising a process of forming silicide on the upper face of the source region.

16. The method according to claim 14, wherein the forming of the exposed insulating film oxidizes the gate interconnection film exposed to the inner face of the contact hole to form the exposed insulating film.

17. The method according to claim 14, wherein the shape of the source region formed between the region immediately below the gate is lattice-shaped when viewed from above, and the interconnection film in the contact hole is connected to the source region in a crossover region of a lattice constituting the lattice shape.

18. A method for manufacturing semiconductor device comprising:
forming a plurality of holes on a semiconductor substrate having formed, on a drain layer of a first conductivity type, a drift region of the first conductivity type having an effective impurity concentration lower than the effective impurity concentration of the drain layer;
forming an insulating film on the inner face of the plurality of holes and the upper face of the semiconductor substrate;
forming a conductive layer on the insulating film so as to fill the hole;
removing the part other than the region inside the hole and immediately above the hole in the conductive film to form a gate electrode, and forming a plurality of gates made of a part on the upper face of the semiconductor substrate in the gate electrode;
removing the part other than on the inner face of the hole in the insulating film to form a gate insulating film;
introducing impurities into an upper layer part of the semiconductor substrate using a plurality of gates as a mask to form a base of the second conductivity type;
introducing impurities into an upper layer part of the third impurity region by using the plurality of gates as a mask to form a source region of the first conductivity type;
forming, on the semiconductor substrate, a first interlayer insulating film filling the space between the plurality of gates;
forming, on the plurality of gates and the first interlayer insulating film, a gate interconnection film electrically connected to the gate electrode exposed on the upper faces of the plurality of gates;
forming a second interlayer insulating film on the gate interconnection film;
forming a contact hole reaching the source region on the second interlayer insulating film, the gate interconnection film, and the first interlayer insulating film;
forming an exposed insulating film on a part in the inner face of the contact hole where the gate interconnection film is exposed; and
forming, on the semiconductor substrate, an interconnection film so as to fill the contact hole and be electrically connected to the source region.
